(19) United States
(12) Patent Application Publication
(10) Pub. No.: US 2015/0357169 A1
(43) Pub. Date: Dec. 10, 2015

(54) SILICON SPUTTERING TARGET WITH ENHANCED SURFACE PROFILE AND IMPROVED PERFORMANCE AND METHODS OF MAKING THE SAME

(71) Applicant: TOSOH SMD, INC., Grove City, OH (US)

(72) Inventors: Yongwen Yuan, Dublin, OH (US); Eugene Y. Ivanov, Grove City, OH (US)

(21) Appl. No.: 14/758,645

(22) PCT Filed: Jan. 3, 2014
(86) PCT No.: PCT/US2014/010142

§ 371 Date: Jun. 30, 2015

Related U.S. Application Data
(60) Provisional application No. 61/848,472, filed on Jan. 4, 2013.

(51) Int. Cl. H01J 37/34; B23K 1/00; B23K 35/26; B23K 35/24; B23K 35/02; C23C 14/34; B23K 1/20

(52) U.S. Cl. CPC H01J 37/3423; C23C 14/3414; H01J 37/3426; B23K 1/0008; B23K 1/20; B23K 35/24; B23K 35/0238; B23K 35/0233; B23K 35/262

(57) ABSTRACT

A sputtering target assembly and method of manufacturing the sputtering target assembly is provided. The sputtering target assembly may have a target blank. The target blank may have at least one planar surface with a thickness T1 and a concave center with a thickness T2, wherein T2 is less than T1.

### CROSS REFERENCE TO RELATED APPLICATION

This PCT application claims the priority benefit of U.S. Provisional Patent Application Ser. No. 61/848,472 filed Jan. 4, 2013 and herein incorporated in its entirety by reference.

### FIELD OF INVENTION

The subject matter disclosed herein relates to sputtering targets for use in physical vapor deposition (PVD) processes, more specifically, silicon sputtering targets.

### BACKGROUND OF THE INVENTION

In typical sputtering processes, silicon atoms from the sputtering target are deposited onto a substrate in a physical vapor deposition (PVD) atmosphere. Most of the sputtered atoms travel, as desired, directly to the substrate. However, a significant portion of the sputtered particles become scattered in the gas during the PVD process and can deposit on various unintended surfaces of the chamber, such as the shield, and target sidewall or flange.

The scattered sputtered particles that deposit onto the various undesired surfaces of the sputter chamber such as the shield or target sidewall and flange, tend to build-up and flake off during later sputtering processes. Deposition of scattered sputtered particles on the target is especially troublesome. For instance, the repeated heating and cooling of the target, including the undesired deposited particles on the sidewalls of the target, render flaking of the particles even more likely, or may result in chipping or cracking of the target or redeposited particles.

In many cases, these deleterious particles are propelled to the substrate. These particles on the wafer may create uneven sputtered films or defects in the sputtered pattern that can lead to a failed circuit. Target lifetime should be determined primarily by target thickness. In practice, however, the target life is often limited by accumulation of deposits or cracks on the target, particularly in the center, near the edges or on the sidewall portion.

Normal silicon (Si) sputtering targets have a flat top surface and straight sidewall. Redeposited silicon with resistivity and amorphous structure is easily built up at the target surface center and edge areas sputtered in radio frequency physical vapor deposition (RF PVD) systems and processes. This results in target surface chipping or cracking and ultimately a short target life time.

### BRIEF DESCRIPTION OF THE INVENTION

By contrast, the sputtering target of the present invention has an enhanced surface profile that surprisingly reduces redeposition of target material and depresses target chipping thereby increasing the target lifetime, improving target sputtering performance and the deposited film quality.

Accordingly, in one embodiment, a sputtering target assembly with an enhanced surface profile is disclosed. The target assembly may comprise a target blank and a backing plate. The target blank may have at least one planar surface with a thickness T1 and a concave center with a thickness T2, wherein T2 may be less than T1. In another embodiment, the target blank may further comprise a beveled edge with a thickness T3 around the perimeter of the target blank. The thickness T3, may be less than T1. In another embodiment, the sputtering target assembly may be generally circular and the first beveled edge may be a continuous beveled edge around the circumference of the target blank.

In yet another embodiment, the target blank may comprise silicon (Si). The silicon target blank may have a diameter up to 550 mm and can be intrinsic, p-type doped, or n-type doped. The silicon blank can have polycrystalline, single crystal, or semi-single crystal structure. In yet another embodiment, the target blank may comprise n-type doped silicon or silicon with n-type conductivity.

In another embodiment, the backing plate may be made of materials including, but not limited to, Al, Mo, Ti, Zr, Ta, Hf, Nb, W, Cu, combinations thereof, and alloys thereof, such as Mo/Cu or Ti/Al composites. In one embodiment, the backing plate may be pure molybdenum with a purity of 2N5 or higher. In yet another embodiment, the target backing plate may be a molybdenum copper composite with copper diffusion bonded or coated to a molybdenum blank. In another embodiment, the backing plate may be a titanium and aluminum composite with aluminum diffusion bonded or coated to a titanium blank.

Methods of manufacturing silicon sputtering targets with an enhanced surface profile are also disclosed. The methods may comprise machining a target blank to have a machined surface having at least one planar surface with a thickness T1 and a concave center with a thickness T2, wherein T2 may be less than T1. In another embodiment, the method may further comprise machining a first beveled edge with a thickness T3 around the perimeter of the target blank. The thickness T3 may be less than T1.

In another embodiment, the target blank may be solder bonded and/or braze bonded to a backing plate to form a target assembly. In yet another embodiment, the solder may be, but is not limited to, indium, tin-silver, laminated foil, and brazed foil.

In another embodiment, the target blank may be generally circular and the first beveled edge may be a continuous beveled edge around the circumference of the target blank. The machined surface may be cleaned and polished after machining to the desired smoothness. The target blank may be obtained by cutting a silicon (Si) slice from a Si ingot and then machining the target blank as described above. Thus, in another embodiment, the target blank may comprise silicon (Si).

### BRIEF DESCRIPTION OF THE DRAWINGS

FIG. 1 is a cross-sectional view illustration of one embodiment of a target in accordance with the invention.

FIG. 1A is a top view illustration of one embodiment of a target in accordance with the invention.

FIG. 1B is a cross-sectional view illustration of the target shown in 1A.

FIG. 1C is a detailed view of a portion of the embodiment shown in FIG. 1B.

FIG. 1D is a detailed view of another portion of the embodiment shown in FIG. 1B.

FIG. 2A is a cross-sectional illustration of a prior art target.

FIG. 2B is a cross-sectional illustration of the erosion profile of a prior art target.

FIG. 3A shows a prior art test target after 20 kW·h.

FIG. 3B shows the same prior art test target in 3A after 178 kW·h.

FIG. 3C shows the same prior art test target in 3A after 201 kW·h.

FIG. 4 shows is the erosion profile of the prior art test target shown in 3C after 201 kW·h.

FIG. 5 shows the same prior art test target in 3A after 201 kWh with the portions of the target that were analyzed using electron backscattered diffraction (EBSD) indicated.

FIG. 5A shows the EBSD results for portion “E” shown in FIG. 5.

FIG. 6A is a pole figure for portion “D” shown in FIG. 5.

FIG. 6B shows a detailed pole figure for portions “C” and “D” shown in FIG. 5.

FIG. 7A shows an illustration of the same prior art test target in 3A after 201 kW·h with the portions of the target that were measured for resistivity.

FIG. 7B is a table of the resistivity measurements.

FIG. 8A is a schematic of the laboratory test used to simulate the performance of the prior art test target shown in 3A after 201 kW·h in the RF PVD process.

FIG. 8B is a graph showing the input current vs. output voltage for various portions of the prior art test target during the laboratory tests.

FIG. 9 shows the prior art test target after the laboratory tests were performed on the target shown in 3A.

FIG. 10 shows the particle performance of one embodiment of a target in accordance with the invention.

### DETAILED DESCRIPTION OF THE INVENTION

The sputtering target assembly of the present invention may comprise a target blank and a backing plate. The target blank may have at least one planar surface with a thickness T1 and a concave center with a thickness T2, wherein T2 is less than T1. In another embodiment, the target blank may further comprise a beveled edge with a thickness T3 around the perimeter of the target blank. The thickness T3 may be less than T1.

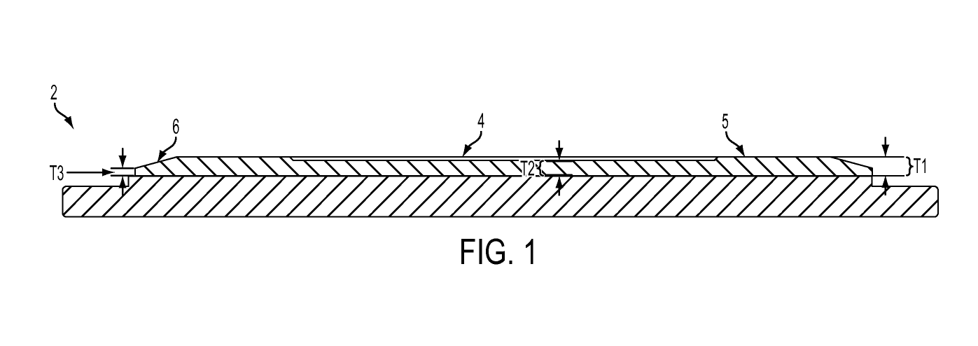

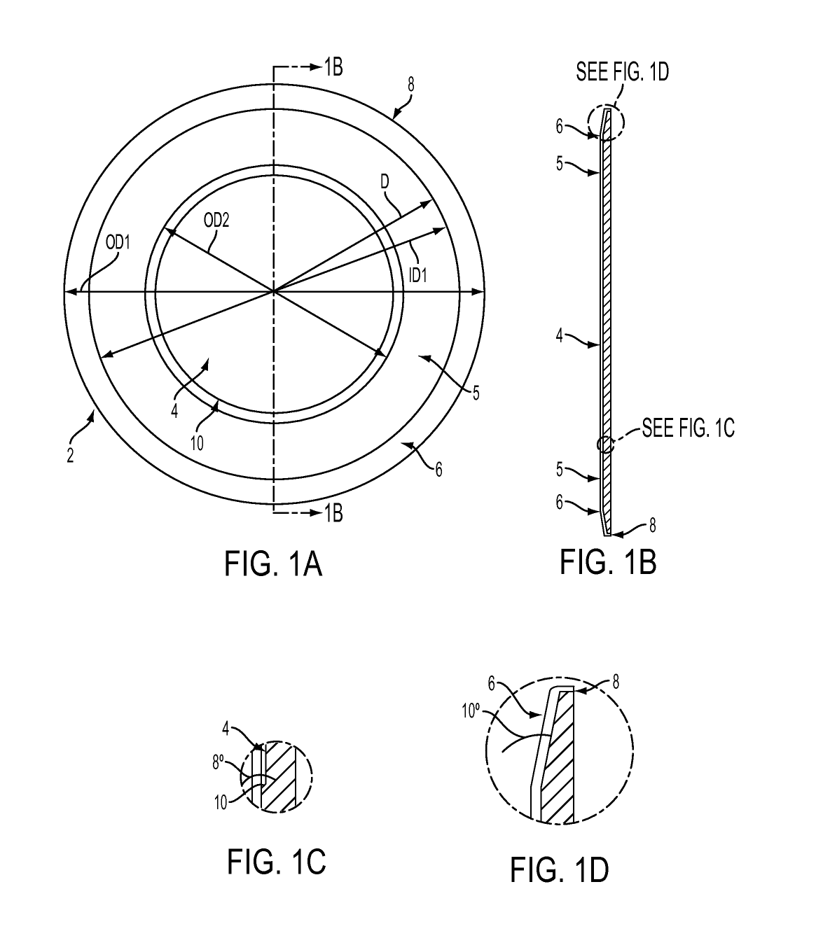

The target blank may be rectangular or circular with a concave center 4 with a thickness T2 that is recessed with respect to the planer surface. The concave center 4 may be a depression with a flat bottom surface and sides that are generally perpendicular with respect to the bottom surface. In one embodiment, the target blank may have a rectangular cross-section. In another embodiment, the target blank may be circular. The target blank may have a first beveled edge with a thickness T3 around the outer perimeter or circumference of the target blank. The thickness T3 may be less than T1. In another embodiment, the sputtering target assembly may be generally circular and the first beveled edge may be a continuous beveled edge around the circumference of the target blank. Turning to FIG. 1, a cross-sectional view illustration of one embodiment of a target 2 in accordance with the invention is shown. The target may be a circular target with at least one planar or flat surface 5 with a thickness T1. The target 2 may have an enhanced surface profile comprising a concave center or “pocket” 4 with a thickness T2 that is recessed with respect to the flat surface 5 of the target 2. The target 2 may also have a first beveled edge 6 with an average thickness T3. The thicknesses T2 and T3 of the concave center 4 and first beveled edge 6 may be less than the target thickness T1 to enhance the sputtering rate and reduce the redeposition at these surfaces when the targets are sputtered in the PVD system using RF power. This enhanced surface profile may depress or reduce target chipping and/or cracking thereby increasing the target life time and improving the deposited film uniformity.

As shown in FIGS. 1A and 1B, the concave center 4 of the target 2 may form a concentric circle within the outer edge 8 of the target 2. FIGS. 1C and 1D are detailed views of portions of the embodiment shown in FIG. 1B. The concave center 4 may be a depression with a flat bottom surface and sides that are generally perpendicular with respect to the bottom surface. Optionally, the concave center 4 may be spherically shaped or shaped like a right frustum cone. The concave center 4 may optionally have a second beveled edge 10 around the outer perimeter of the concave center. The angle of the second beveled edge 10 of the concave center or “pocket” 4 may range from 85° to about 5°. As may be seen in FIG. 1C, the second beveled edge 10 of the concave center may have an angle of about 8°.

The edge 8 may a have a first beveled edge 6 around the circumference of the target. As shown in FIG. 1D, the bevel need not extend the entire thickness T1 of the target, but may form a chamfered edge. The angle of the first beveled edge 6 at the target edge 8 may range from about 85° to about 5°. As may be seen in FIG. 1D, the first beveled edge 6 at the target edge 8 may have an angle about 10°.

The length of the first and second beveled edges 6 and 10 may be the same or different. The beveled edge (6 or 10) length may vary and may be any suitable length anticipated by those of ordinary skill of the art.

In one embodiment, the target blank may have an outer diameter OD1. In one embodiment, the OD1 may be less than or equal to 550 mm. The bevel of the first beveled edge 6, may start from a distance, D from the center of the circular target 2, and extend to the target's outer diameter OD1 and form a concentric circle with an inner diameter ID1 within the target's outer diameter OD1. ID1 may range from equal to or greater than about 81% to about 99% of the target blank's outer diameter OD1. In another embodiment, ID1 may range from about 85% to about 95% of the target blank's outer diameter OD1. In yet another embodiment, ID1 may be about 88% of the target blank's outer diameter OD1.

The concave center 4 may have an outer diameter OD2. OD2 may range from about 50% to about 80% of the target blank's diameter OD1. The remaining area of the target between the outer diameter OD2 of the concave center 4 and the inner diameter ID1 may be a planar or flat surface 5. The remaining area of the target with a planar or flat surface 5 may have a thickness, T1.

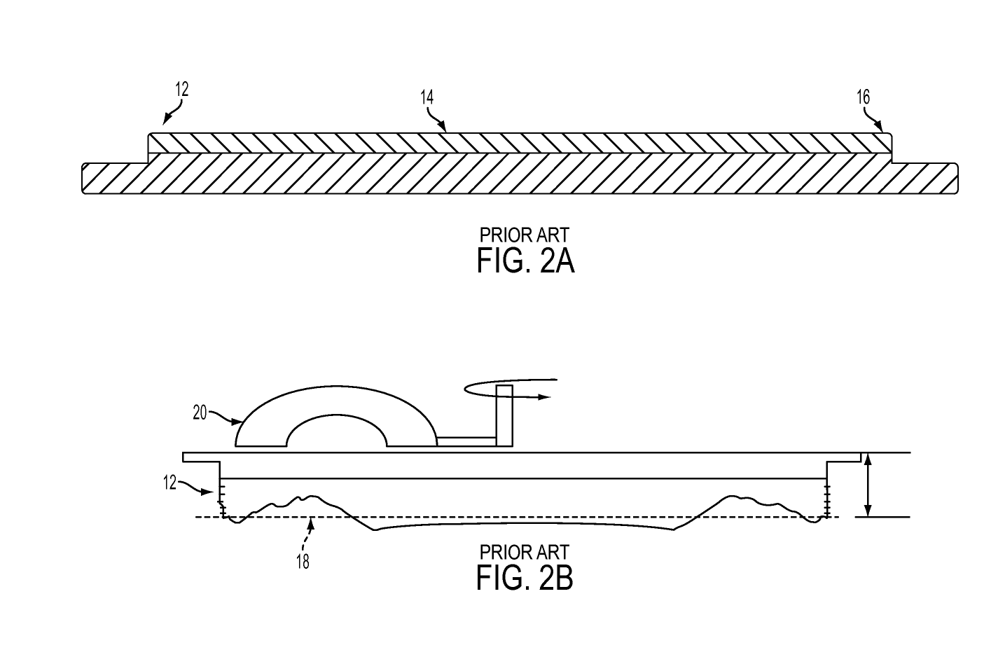

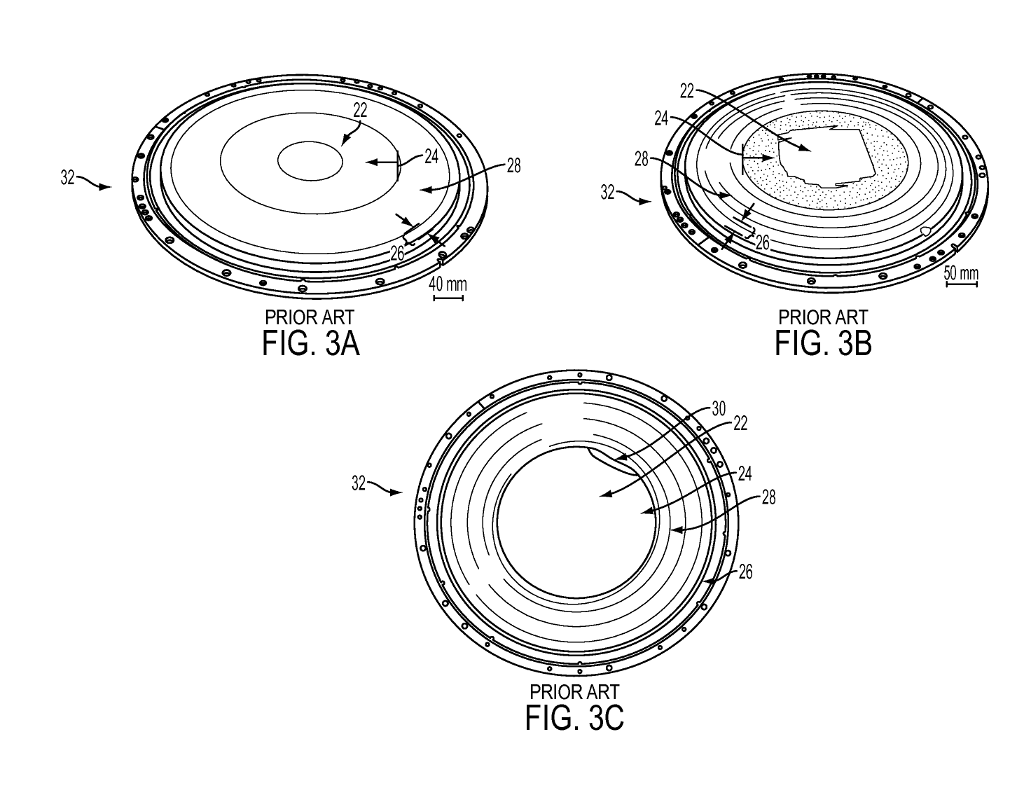

This is in contrast to the prior art, or flat, target 12 shown in FIG. 2A with a flat surface 14 that is planar across the entire target surface. The prior art target 12 also has a straight edge 16 around the entire target edge(s). Turning to FIG. 2B, when sputtered in the RF PVD process, the original surface, as indicated by the dashed line 18, of the flat target is prone to redeposition near the magnetic poles of the magnet 20.

Without limiting this disclosure to one theory of operation, it is thought that redeposition layers have a different structure and higher resistivity and different type of conductivity, (e.g. n-type redeposition can form on P-type target materials or vice versa) as compared to the target matrix material. This may result in local current or energy that is generated on the accumulated redeposition layers, thereby causing chipping or cracking of the redeposition layers and target material itself during the sputtering process. Test results showed that redeposited material comprised mostly n-type silicon whereas the blank target material comprised mostly p-type silicon. The n-type to p-type junction between the blank target material and the n-type redeposited material may also be prone to chipping or cracking.

Accordingly, in another embodiment, the target blank may comprise silicon and can be intrinsic, p-type doped, or n-type doped or have n-type conductivity. The silicon blank can have polycrystalline, single crystal, or semi-single crystal structure. In yet another embodiment, the silicon blank may be made of n-type doped silicon to avoid forming junctions between more than one type of silicon thereby reducing chipping or cracking.

The backing plate may be made of materials including, but not limited to, Al, Mo, Ti, Zr, Ta, Hf, Nb, W, Cu, combinations thereof, and alloys thereof. Exemplary combinations of backing plate materials include Mo/Cu or Ti/Al composites. In one embodiment, the backing plate may be pure molybdenum with a purity of 2N5 or higher. In yet another embodiment, the backing plate blank may be a molybdenum copper composite with copper diffusion bonded or coated to a molybdenum blank. In another embodiment, the baking plate may be a titanium and aluminum composite with aluminum diffusion bonded or coated to a titanium blank.

The target 2 may have an improved target lifetime over the prior art target 12. Accordingly, in one embodiment, the sputtering target assembly may have a lifetime greater than 250 kW·h or greater than 5,000 wafers.

Methods of manufacturing silicon sputtering targets with an enhanced surface profile are also disclosed. The methods may comprise machining a target blank to have a machined surface having at least one planar surface with a thickness T1 and a concave center with a thickness T2, wherein T2 may be less than T1. In another embodiment, the method may further comprise machining a first beveled edge with a thickness T3 around the perimeter of the target blank. The thickness T3 may be less than T1.

In another embodiment, the target blank may be solder bonded and/or braze bonded to a backing plate to form a target assembly. In yet another embodiment, the solder may be, but is not limited to, indium, tin-silver, brazed foil, and laminated foil. An exemplary laminated foil is NanoFoil® available from Indium Corporation, Utica, N.Y.

In another embodiment, the target blank may be generally circular and the edge may be a continuous beveled edge around the circumference of the target blank. The machined surface may be cleaned and polished after machining to the desired smoothness. The target blank may be obtained by cutting a silicon (Si) slice from a Si ingot and then machining the target blank as described above. Thus, in another embodiment, the target blank may comprise silicon (Si).

Films prepared using the target 2 may have a film uniformity of about 1-2% versus about 5% for films made with a prior art target 12. In some embodiments of the invention, the target 2, may produce films with low particle counts, equal to or less than, 5 particles per wafer. The target 2, may also have a short burn-in time less than or equal to 8 hours.

### EXAMPLES

A flat, prior art test target 32 as shown in FIG. 2A was sputtered in a PVD system using RF power. FIG. 3A shows the test target after 20 kW·h. The portions of the test target most prone to redeposition were the center redeposition area 22, the center redeposition and chipping area 24, and the edge redeposition and chipping band 26. The sputtered traces 28, are not as prone to redeposition. FIG. 3B shows the same test target 32 after 178 kW·h. The test target 32 started to chip or crack 30 after 201 kW·h and is shown in FIG. 3C. After the test target 32 started to chip, it was no longer suitable for use in the sputtering process and it was removed for analysis and further testing in a laboratory setting.

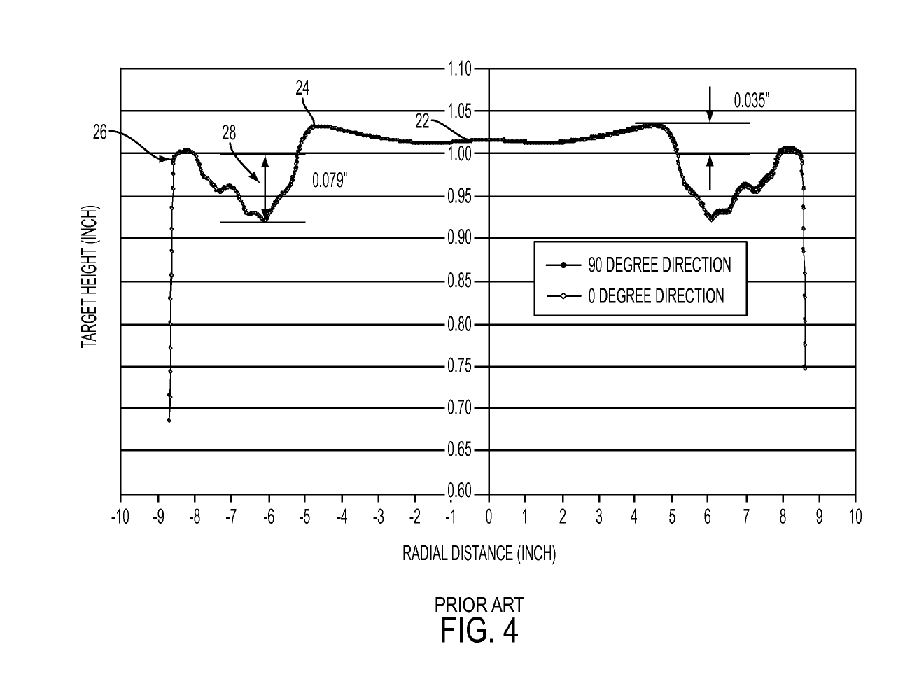

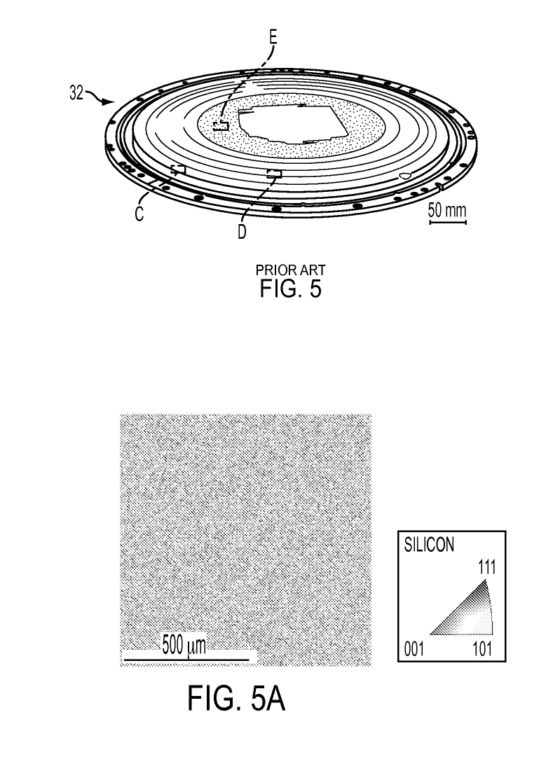

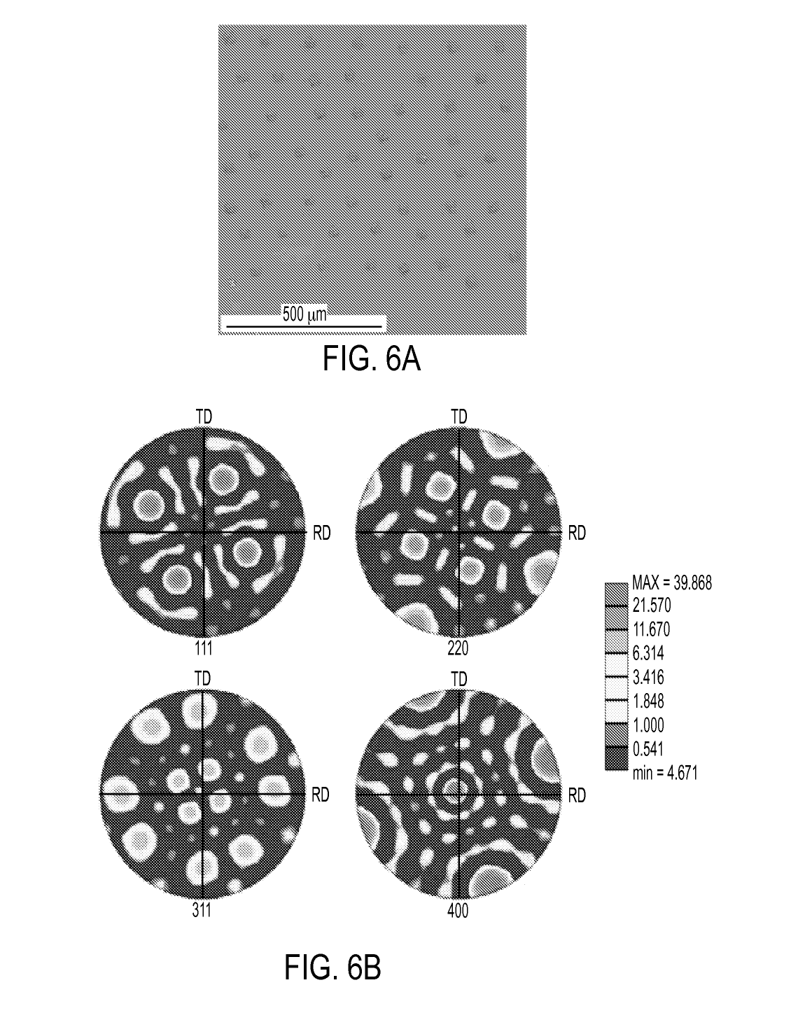

The test target 32 thickness after 201 kW·h was measured and plotted to create an erosion profile shown in FIG. 4. After the test target 32 thickness was measured, the test target 32 was analyzed using electron backscattered diffraction (EBSD) to determine the crystalline orientation of the target material. Portions C, D, and E of the test target 32 were analyzed and are indicated in FIG. 5. A detailed picture of portion E is shown in FIG. 5A. As may be seen in FIG. 5A, the silicon in portion E had an amorphous structure without Kikuchi patterns. Portions C and D from the sputtered traces area 28, however, showed a crystalline silicon Si(100) orientation as may be seen in FIGS. 6A and 6B.

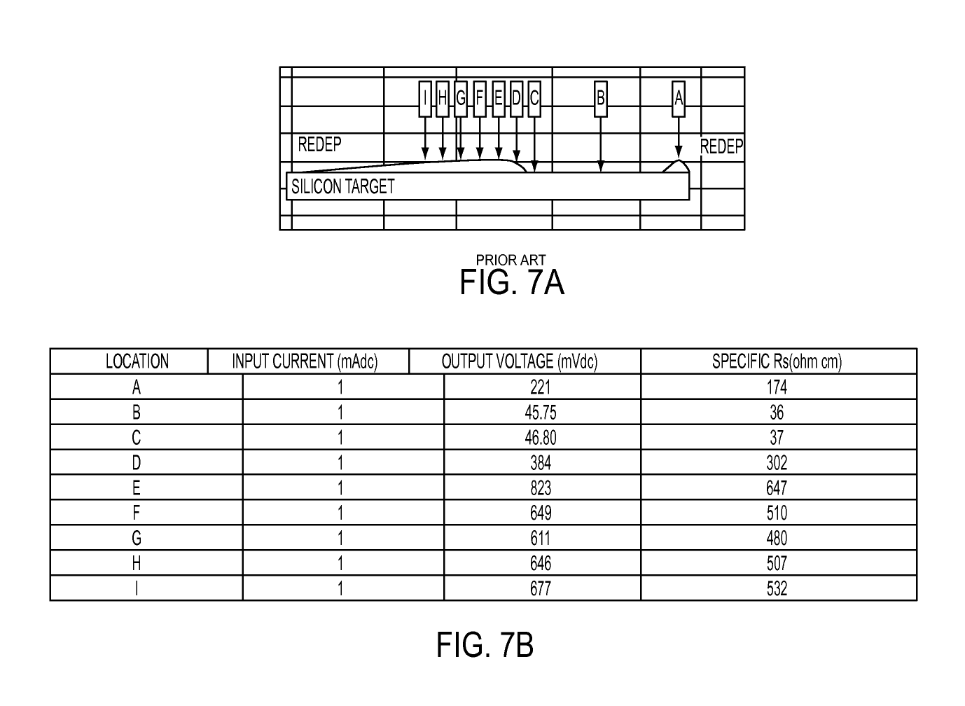

Various portions (A-I) shown in FIG. 7A of the test target 32 after 201 kW·h were measured for resistivity. The results are shown in FIG. 7B. As may be seen in FIG. 7B, the redeposited areas have increased resistivity as compared to the sputtered trace area. The resistivity may be an indication of the amount of material redeposited on the target.

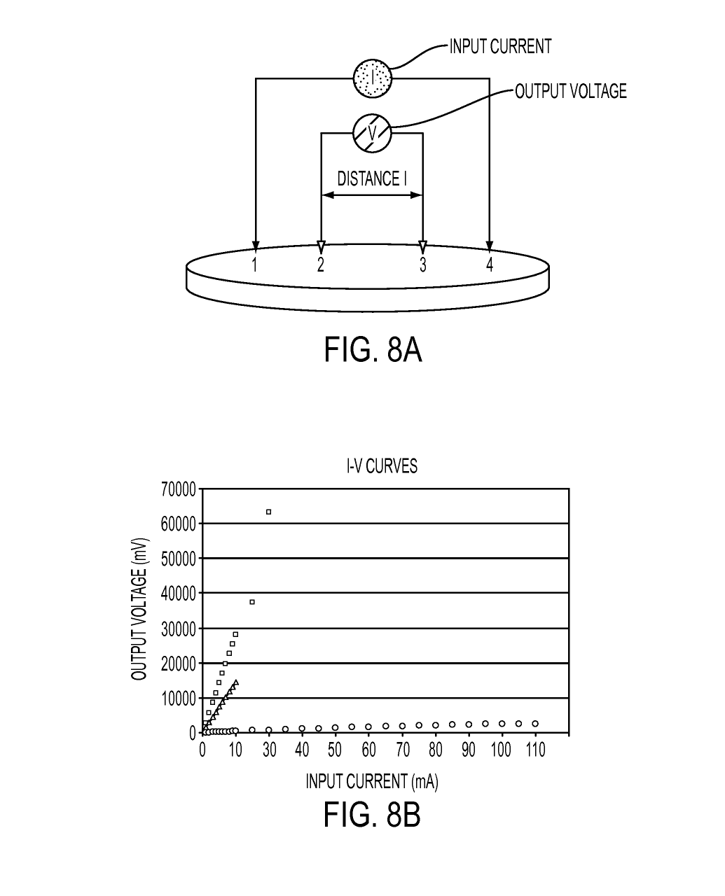

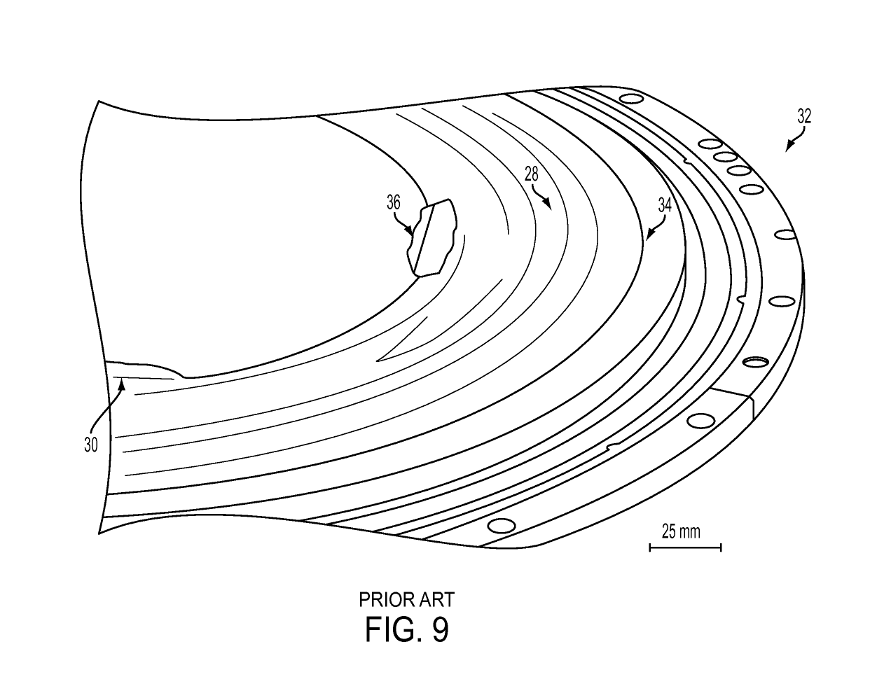

FIG. 8A is schematic of the laboratory test used to simulate the performance of the test target 32 shown in 3A after 201 kW·h in the RF PVD process. Points 1 and 4 in FIG. 8A were located in the sputtered trace area with p-type silicon. Points 2 and 3 in FIG. 8A were located in the redeposited area comprising n-type silicon. A current was applied to points 1 and 4 of and the output voltage was measured at points 2 and 3 of the test target 32 after 201 kW·h. FIG. 8B is a graph showing the input current vs. output voltage of the test target 32 during the laboratory tests. Cracking started to occur 34 at the edge redeposition and chipping band 26 when 20 mA was applied. Catastrophic cracking 36 (FIG. 9) occurred in the center redeposition and chipping area 24 when 100 mA was applied. The sputtered traces 28 of the target material remained intact and did not crack while the 100 mA was applied.

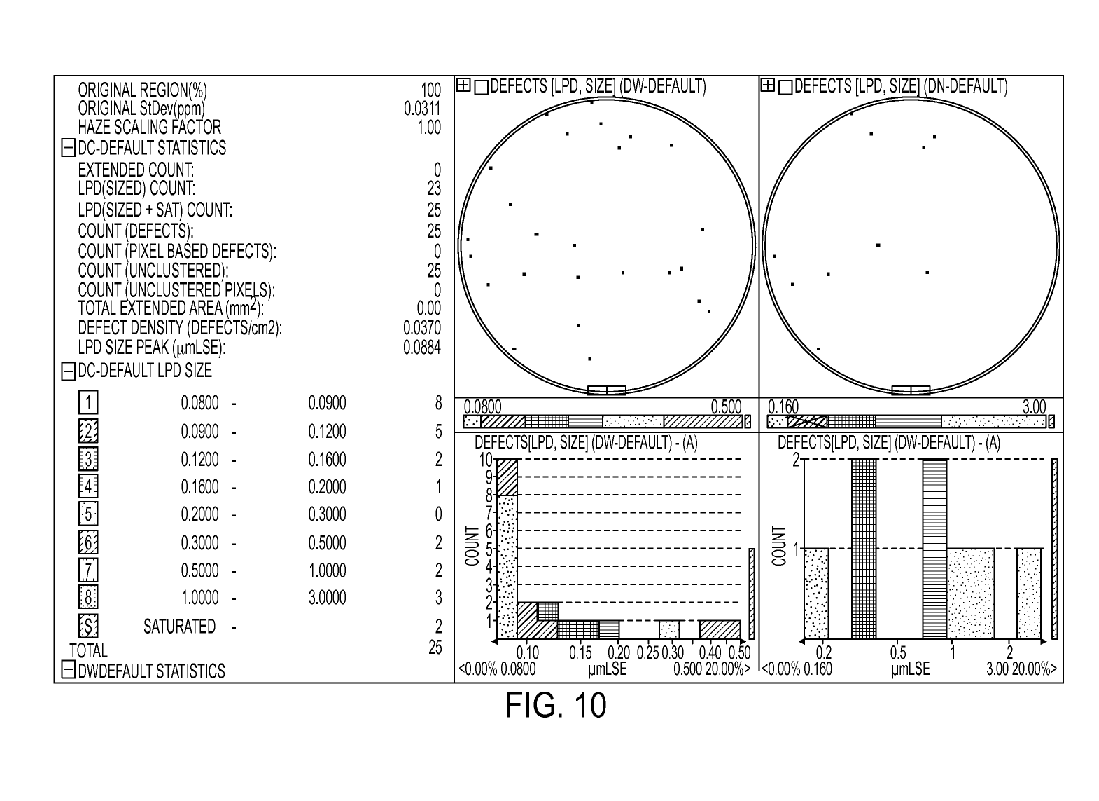

A target 2, according to one aspect of the invention, with an improved profile comprising a concave center 4 and a first beveled edge 6 was also sputtered in a RF PVD process. The target 2 had an improved target lifetime over the test target 32 with the profile 12. The target had a lifetime greater than 250 kW·h or greater than 5,000 wafers. By reducing the amount of redeposited material on the target, the target lifetime may increase. Reducing the amount of redeposited material may reduce the amount of flaking or chipping in the target thereby reducing the amount of particles that are propelled to the substrate or wafer. Accordingly, in some embodiments of the invention, the target 2, may produce films with low particle counts, equal to or less than, 5 particles per wafer. FIG. 10 shows the particle performance of one embodiment of a target in accordance with the invention.

Likewise, films prepared using the inventive target may exhibit a film uniformity of about 1-2% versus about 5% for films made with a prior art target 12. The inventive target, may also have a shorter burn-in time compared to a prior art target 12. The burn-in time of the target 2 may be less than or equal to 8 hours. FIG. 10 shows the particle performance of one embodiment of a target in accordance with the invention.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A sputtering target assembly comprising a target blank and a backing plate, wherein said target blank has at least one planar surface with thickness T1, a concave center with a thickness T2 and wherein T2 is less than T1.

2. The sputtering target assembly of claim 1, wherein said target blank further comprises a first beveled edge with a thickness T3 around a perimeter of said target blank and wherein T3 is less than T1.

3. The sputtering target assembly of claim 2, wherein said target assembly is generally circular and wherein said first beveled edge is a continuous beveled edge around the circumference of said target blank.

4. The sputtering target assembly of claim 1, wherein said target blank comprises silicon (Si).

5. The sputtering target assembly of claim 1, wherein said backing plate is made of materials selected from the group consisting of Al, Mo, Ti, Zr, Ta, Hf, Nb, W, Cu, combinations thereof, and alloys thereof.

6. The sputtering target assembly of claim 5, wherein said backing plate is molybdenum with a purity equal to or greater than 2N5.

7. The sputtering target assembly of claim 6, wherein said backing plate is a molybdenum copper composite with copper diffusion bonded or coated to said pure molybdenum blank.

8. A method of making a sputtering target, said method comprising machining a target blank to have a machined surface having at least one planar surface with a thickness T1, a concave center with a thickness T2 and wherein T2 is less than T1.

9. The method of claim 8, further comprising machining a first beveled edge with a thickness T3 around a perimeter of said target blank and wherein T3 is less than T1.

10. The method of claim 8, further comprising solder bonding and/or braze bonding said target blank to a backing plate to form a target assembly.

11. The method of claim 10, wherein said solder and/or braze bonding further comprises using a solder selected from the group consisting of indium, tin-silver, laminated foil, and brazed foil.

12. The method of claim 8, further comprising polishing said machined surface.

13. The method of claim 8, wherein said target blank is generally circular and wherein said first beveled edge is a continuous beveled edge around the circumference of said target blank.

14. The method of claim 8, wherein said target blank comprises silicon (Si).
